(19) United States
(12) Patent Application Publication
(10) Pub. No.: US 2024/0393700 A1
(43) Pub. Date: Nov. 28, 2024

(54) INFORMATION PROCESSING APPARATUS, EXPOSURE APPARATUS, AND ARTICLE MANUFACTURING METHOD

(71) Applicant: CANON KABUSHIKI KAISHA, Tokyo (JP)

(72) Inventors: JUN KITAGAWA, Tochigi (JP); HIROAKI SHIRAO, Tochigi (JP); SHINGO YONEDA, Tochigi (JP); WATARU KIJIMA, Tokyo (JP); YUTA TAKAI, Tochigi (JP)

(21) Appl. No.: 18/791,686

(22) Filed: Aug. 1, 2024

Related U.S. Application Data
(63) Continuation of application No. PCT/JP2022/046803, filed on Dec. 20, 2022.

(30) Foreign Application Priority Data
Mar. 28, 2022 (JP) 2022-051084

(51) Int. Cl. G03F 7/00; G05B 13/02

(52) U.S. Cl. CPC G03F 7/705; G03F 7/70258; G03F 7/70325; G03F 7/70508; G03F 7/70875; G03F 7/70891; G05B 13/0265

(57) ABSTRACT

In order to provide an information processing apparatus capable of obtaining a variation amount in an optical characteristic of an optical system provided in an exposure apparatus in consideration of a control for suppressing a temperature variation of the optical system, the information processing apparatus according to the present invention is configured to predict the variation amount in the optical characteristic of the optical system by inputting a target temperature of the optical system to a learning model, in which the learning model is a learning model obtained by machine learning.

### CROSS-REFERENCE TO RELATED APPLICATIONS

This application is a Continuation of International Patent Application No. PCT/JP2022/046803, filed Dec. 20, 2022, which claims the benefit of Japanese Patent Application No. 2022-051084, filed Mar. 28, 2022, both of which are hereby incorporated by reference herein in their entirety.

### BACKGROUND OF THE INVENTION

### Field of the Invention

The present invention is related to an information processing apparatus, and more particularly, to an information processing apparatus which predicts a variation amount in an optical characteristic of an optical system provided in an exposure apparatus.

### Description of the Related Art

In an exposure apparatus, it is known that optical characteristics of an optical system change when temperature of the optical system changes due to the optical system absorbing energy of exposure light.

Japanese Patent Application Laid-Open No. H05-78008 discloses an exposure apparatus which measures a temperature distribution in a predetermined optical element in a projecting optical system by using a temperature measuring element provided in the predetermined optical element to calculate a variation amount in an optical characteristic of the projecting optical system based on the measured temperature distribution.

In the exposure apparatus, for example, control for suppressing temperature change of an optical system may be performed by supplying temperature-adjusted gas toward the optical system.

In such case, in addition to the temperature change of the optical system, the control for suppressing the temperature change of the optical system also contributes to changes in optical characteristics of the optical system.

### SUMMARY OF THE INVENTION

An object of the present invention is to provide an information processing apparatus capable of acquiring a variation amount in an optical characteristic of an optical system provided in an exposure apparatus in consideration of control for suppressing temperature change of the optical system.

The information processing apparatus according to the present invention is configured to predict a variation amount in an optical characteristic of an optical system provided in an exposure apparatus by inputting a target temperature of the optical system to a learning model, in which the learning model is a learning model obtained by machine learning.

Further features of the present invention will become apparent from the following description of exemplary embodiments with reference to the attached drawings.

### BRIEF DESCRIPTION OF THE DRAWINGS

FIG. 1 is a block diagram of an exposure apparatus including an information processing apparatus according to a first embodiment of the present invention.

FIG. 2A is a flowchart showing a process for correcting a variation amount in an optical characteristic of a projecting optical system by using the information processing apparatus according to the first embodiment.

FIG. 2B is a flowchart showing a process for creating an optical characteristic predicting model by using the information processing apparatus according to the first embodiment.

FIG. 3 is a flowchart showing a process for correcting the variation amount in the optical characteristic of the projecting optical system by using an information processing apparatus according to a second embodiment of the present invention.

### DESCRIPTION OF THE EMBODIMENTS

Hereinafter, an information processing apparatus according to the present invention will be described in detail with reference to the accompanying drawings. Note that the drawings shown below are drawn on a scale different from the actual scale in order to facilitate understanding of the present invention.

### First Embodiment

In an exposure apparatus, it is known that optical characteristics of a projecting optical system change when temperature of the projecting optical system changes due to the projecting optical system absorbing energy of exposure light.

Several methods for measuring the variation in the optical characteristic of the projecting optical system provided in the exposure apparatus are known.

For example, a method is known in which a line width of a circuit pattern formed on a substrate that has been exposed and developed is measured to measure a variation amount in the optical characteristic of the projecting optical system from the measurement result.

Further, there is known a method of measuring a light amount of an exposure image on the imaging plane of the projecting optical system by using a photoelectric sensor to measure the variation amount in the optical characteristic of the projecting optical system from the measurement result.

In the exposure apparatus, the optical characteristic of the projecting optical system is corrected by adjusting an imaging position of the projecting optical system based on the variation amount in the optical characteristic of the projecting optical system measured by using such method.

Further, a method is known in which the variation amount in the optical characteristic of the projecting optical system caused by a temperature change due to absorption of exposure energy in the projecting optical system is calculated from temperature information and temperature gradient information obtained from a thermometer attached to the projecting optical system to correct the variation amount based on the calculation result.

That is, the method directly detects a variation in the optical characteristic of the projecting optical system regardless of an exposure state.

In addition, a method is known in which the variation amount in the optical characteristic of the projecting optical system is calculated from a plurality of measurement results including atmospheric pressure, temperature, and humidity around the exposure apparatus and the exposure image on the imaging plane to correct the variation amount in the optical characteristic at the timing when it is determined that the variation amount in the optical characteristic is large.

As described above, when the temperature of the projecting optical system provided in the exposure apparatus changes, the optical characteristic of the projecting optical system change, and more specifically, a shift of a focus occurs, for example.

In this case, in order to transfer a pattern formed on a mask onto a substrate with high accuracy, namely with high contrast, a focus adjustment for aligning the substrate with a focal position of the projecting optical system is required.

In the exposure apparatus, a shift amount of the focus is calculated from measurement results of a light amount received by a photoelectric sensor provided on a substrate stage and a position of the substrate stage.

However, since the substrate arranged on the substrate stage cannot be irradiated with exposure light when such measurement is performed, increasing the number of times of measurement leads to a decrease in productivity in the exposure apparatus.

In addition, in order to suppress the decrease in the productivity in the exposure apparatus to predict the shift amount of the focus without measurement, high accuracy is required in the prediction.

Further, when the variation amount in the optical characteristic of the projecting optical system is calculated from the thermometer attached to the projecting optical system, it is difficult to arrange the thermometer on an optical path of the exposure light, which affects accuracy of the exposure image, due to durability of the thermometer.

Accordingly, it is difficult to accurately calculate the variation amount in the optical characteristic of the projecting optical system from the thermometer attached to the projecting optical system.

The present invention provides an information processing apparatus which can predict to correct a variation amount in an optical characteristic of an optical system with high accuracy from temperature information of the optical system provided in an exposure apparatus, temperature adjustment history of each unit provided in the exposure apparatus, and structure information and operation information of the exposure apparatus.

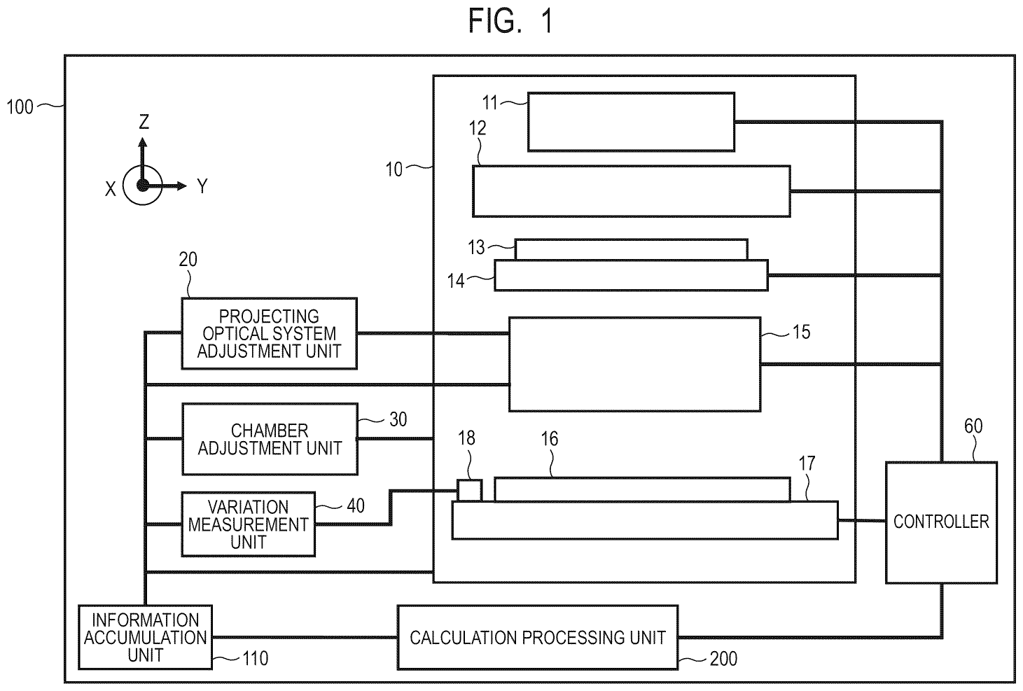

FIG. 1 shows a block diagram of an exposure apparatus 100 including an information processing apparatus according to a first embodiment of the present invention.

Hereinafter, a direction perpendicular to a substrate surface of the substrate 16 is defined as a Z direction, and two directions orthogonal to each other in a plane parallel to the substrate surface are defined as an X direction and a Y direction.

The exposure apparatus 100 includes an exposure light source 11, an illuminating optical system 12 (an optical system), a mask stage 14 (an original stage), a projecting optical system 15 (an optical system), and a substrate stage 17, which are accommodated in a chamber 10.

Further, the exposure apparatus 100 includes a projecting optical system adjustment unit 20, a chamber adjustment unit 30, a variation measurement unit 40 (a measurement unit), a controller 60, an information accumulation unit 110 (a storing unit), and a calculation processing unit 200 (an information processing apparatus).

In the exposure apparatus 100, the projecting optical system 15 is accommodated in a housing, and space in the housing is isolated from space in the chamber 10 such that gas does not flow in and out.

In the following description, temperature and pressure of the projecting optical system 15 refer to temperature and pressure of the space in the housing in which the projecting optical system 15 is accommodated.

In the exposure apparatus 100, exposure light emitted from the exposure light source 11 is shaped by the illuminating optical system 12, and then irradiated (guided) onto a mask 13 placed on the mask stage 14.

Then, the exposure light that has passed through a transmission portion of the mask 13, which forms an exposure pattern, is condensed (guided) onto a substrate 16 placed on the substrate stage 17 by the projecting optical system 15.

Thereby, the exposure pattern formed (drawn) on the mask 13 is projected (transferred) onto the substrate 16.

The projecting optical system adjustment unit 20 measures temperature and pressure of the projecting optical system 15 by using a thermometer and a manometer (not shown) mounted on the projecting optical system 15 to control the temperature and the pressure of the projecting optical system 15 to be kept constant.

Specifically, the projecting optical system adjustment unit 20 supplies gas whose temperature is adjusted (to be referred to as temperature-adjusted gas hereinafter) toward the projecting optical system 15 based on the measurement results of the temperature and the pressure of the projecting optical system 15.

The chamber adjustment unit 30 measures temperature, humidity, and pressure in the chamber 10 by using an environmental meter (not shown) mounted on the chamber 10 to control the temperature, the humidity, and the pressure in the chamber 10 to be kept constant.

Specifically, the chamber adjustment unit 30 supplies the temperature-adjusted gas into the chamber 10 based on the measurement results of the temperature, the humidity, and the pressure in the chamber 10.

The variation measurement unit 40 measures a variation amount in the optical characteristic of the projecting optical system 15 from an amount of light measured by an optical sensor 18, which is mounted on the substrate stage 17 and measures the light condensed by the projecting optical system 15.

Specifically, the variation measurement unit 40 measures the variation amount in a focus or a distortion of the projecting optical system 15 as the variation amount in the optical characteristic of the projecting optical system 15.

However, the present invention is not limited to the above, and the variation amount in the optical characteristic of the projecting optical system 15 may be measured by measuring the exposure pattern transferred onto the substrate 16 using a line width measuring device or a length measuring device (not shown) provided outside the exposure apparatus 100.

The controller 60 controls an output of the exposure light source 11, a position of the illuminating optical system 12, and a position of the projecting optical system 15 when exposure is performed in the exposure apparatus 100, more specifically, the position of a correction mechanism (not shown) provided in the projecting optical system 15.

Further, the controller 60 adjusts a relative position of the substrate 16 with respect to the mask 13 by controlling positions of the mask stage 14 and the substrate stage 17 in the X direction, the Y direction, and the Z direction.

Furthermore, the controller 60 controls an output and a position of each unit by referring to a correction amount of each unit in the exposure apparatus 100 calculated by the calculation processing unit 200, as described later.

The information accumulation unit 110 records operation information and state information of the exposure apparatus 100.

Specifically, the operation information of the exposure apparatus 100 includes control data of the projecting optical system adjustment unit 20, control data of the chamber adjustment unit 30, and a measurement result of the optical characteristic of the projecting optical system 15 measured by the variation measurement unit 40.

Further, the operation information of the exposure apparatus 100 includes control data associated with mechanical operations such as movement of each unit including the illuminating optical system 12, the mask stage 14, the projecting optical system 15, and the substrate stage 17 controlled by the controller 60.

Furthermore, the operation information of the exposure apparatus 100 includes parameters necessary for exposure, namely exposure parameters, such as a target illuminance of the exposure light source 11 in exposure, transmittance and pattern information (type) of the mask 13, and a movement speed of the substrate stage 17.

Then, specifically, the state information of the exposure apparatus 100 includes measurement results of temperature and pressure of the projecting optical system 15 by the thermometer and the manometer mounted on the projecting optical system 15.

Further, the state information of the exposure apparatus 100 includes measurement results of the temperature, humidity, and pressure in the chamber 10 obtained by an environment meter mounted on the chamber 10.

Specifically, a list of sensors arranged to measure the state information of the exposure apparatus 100 is shown in the following Table 1.

TABLE 1

| Mounted position | Kind of meter | Unit |
|---|---|---|
| Inside projecting | Manometer | Pa |
| optical system 15 | Thermometer | ° C. |
| Around projecting | Manometer | Pa |
| optical system 15 | Thermometer | ° C. |
| Inside chamber 10 | Manometer | Pa |
| | Thermometer | ° C. |
| | Hygrometer | % |
| Around chamber 10 | Manometer | Pa |
| | Thermometer | ° C. |
| | Hygrometer | % |
| Inside projecting | Manometer | Pa |
| optical system | Thermometer | ° C. |
| adjustment unit 20 | Temperature adjustment | % |
| | output meter | |
| | Cooling fluid flow rate meter | m³/s |
| Inside chamber | Manometer | Pa |
| adjustment unit 30 | Thermometer | ° C. |
| | Hygrometer | % |
| | Temperature adjustment | % |
| | output meter | |
| | Cooling fluid flow rate meter | m³/s |

As shown in Table 1, the exposure apparatus 100 can measure a relative pressure difference and a relative temperature difference between an inside and a periphery of the projecting optical system 15 by providing a manometer and a thermometer in each of the inside and the periphery of the projecting optical system 15.

Further, the exposure apparatus 100 can measure a relative pressure difference, a relative temperature difference, and a relative humidity difference between an inside and a periphery of the chamber 10 by providing a manometer, a thermometer, and a hygrometer in each of the inside and the periphery of the chamber 10.

The temperature adjustment output meter provided in each of the projecting optical system adjustment unit 20 and the chamber adjustment unit 30 shown in Table 1 measures a magnitude of an output of temperature-adjusted gas supplied from each unit.

The cooling fluid flow rate meter provided in each of the projecting optical system adjustment unit 20 and the chamber adjustment unit 30 shown in Table 1 measures a flow rate of fluid for cooling the temperature-adjusted gas in the temperature-adjusted gas supply source provided in each unit.

Since the exposure apparatus 100 supplies temperature-adjusted dry air as temperature-adjusted gas toward the projecting optical system 15, no hygrometer is provided in the projecting optical system 15 and the projecting optical system adjustment unit 20.

However, the present invention is not limited to this, and a hygrometer may be provided inside the projecting optical system 15 and the projecting optical system adjustment unit 20.

It is effective to provide each sensor shown in Table 1 at a plurality of positions in the exposure apparatus 100, since variations in measurement values can be suppressed and distribution information can be obtained.

Then, the information accumulation unit 110 acquires to record the measurement result of each sensor shown in Table 1 at an arbitrary timing or at a predetermined interval.

The calculation processing unit 200 acquires the variation amount in the optical characteristic of the projecting optical system 15 by using the measurement result of each sensor recorded in the information accumulation unit 110.

Then, the calculation processing unit 200 calculates a correction amount in each unit in the exposure apparatus 100 for correcting the acquired variation amount in the optical characteristic of the projecting optical system 15.

In the present embodiment, the information accumulation unit 110 and calculation processing unit 200 are mounted in the exposure apparatus 100, but the present invention is not limited to this, and the information accumulation unit 110 and calculation processing unit 200 may be provided outside the exposure apparatus 100.

Next, a method of correcting the variation amount in the optical characteristic of the projecting optical system 15 by using the information processing apparatus according to the present embodiment is described.

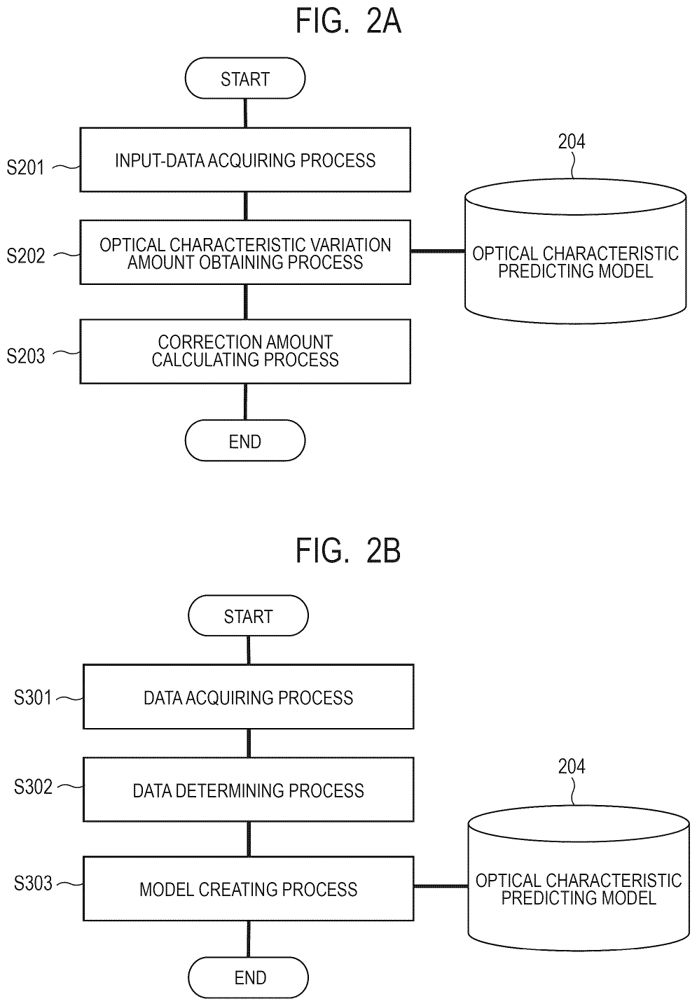

FIG. 2A is a flowchart showing a process for correcting the variation amount in the optical characteristic of the projecting optical system 15 in the calculation processing unit 200.

First, an input-data acquiring process is performed to convert each data recorded in the information accumulation unit 110 into input data (step S201).

Specifically, in step S201, the measurement results of the temperature and the pressure of the projecting optical system 15 by the thermometer and the manometer mounted in the projecting optical system 15, and the target temperature and the target pressure of the projecting optical system 15 by the projecting optical system adjustment unit 20 are acquired from the information accumulation unit 110.

Further, in step S201, the measurement results of the temperature, the humidity, and the pressure in the chamber 10 by the environment meter mounted in the chamber 10, and the target temperature, the target humidity, and the target pressure in the chamber 10 by the chamber adjustment unit 30 are acquired from the information accumulation unit 110.

Furthermore, in step S201, the target position of each unit including the illuminating optical system 12, the mask stage 14, the projecting optical system 15, and the substrate stage 17 in the exposure apparatus 100 controlled by the controller 60 is acquired from the information accumulation unit 110.

In addition, in step S201, exposure parameters such as the configuration of the illuminating optical system 12, the target illuminance of the exposure light source 11 in exposure, the transmissivity and pattern information (type) of the mask 13, and the movement speed of the substrate stage 17 are acquired from the information accumulation unit 110.

Then, in step S201, each data acquired from the information accumulation unit 110 is converted into input data.

The measurement results acquired from the information accumulation unit 110 are subjected to predetermined processing according to the characteristics.

Specifically, an averaging process is executed for measurement values having a relatively large distribution (variation) in a space, such as the temperature of the projecting optical system 15 and the temperature in the chamber 10.

Next, an optical characteristic variation amount obtaining process is performed to obtain the variation amount in the optical characteristic of the projecting optical system 15 by inputting the input date acquired in step S201 to the optical characteristic predicting model 204 (a learning model) (step S202).

The optical characteristic predicting model 204 used in step S202 is a mathematical model which outputs the variation amount in the optical characteristic of the projecting optical system 15 as output data from the input data acquired in step S201.

Then, specifically, the variation amount in the optical characteristic of the projecting optical system 15 output from the optical characteristic predicting model 204 is the variation amount in the focus or the distortion of the projecting optical system 15.

Next, a correction amount calculating process is performed to calculate correction amounts of the output and the position of each unit in the exposure apparatus 100 for correcting the variation amount in the optical characteristic of the projecting optical system 15 obtained in step S202 (step S203).

Specifically, in step S203, the position in the Z direction of the substrate stage 17 in exposure is calculated when the variation amount in the focus of the projecting optical system 15 is corrected among the variation amounts in the optical characteristics of the projecting optical system 15, for example.

Further, the positions of the mask stage 14 and the substrate stage 17 in the XY plane and the position of a distortion correcting mechanism (not shown) of the projecting optical system 15 in exposure are calculated when the variation amount in the distortion of the projecting optical system 15 is corrected among the variation amounts in the optical characteristics of the projecting optical system 15.

Note that the process of correcting the variation amount in the optical characteristic of the projecting optical system 15 in steps S201 to S203 described above may be executed every time exposure is performed on the substrate 16, or may be executed every time exposure is completed for a predetermined number of substrates 16.

Next, a method of creating the optical characteristic predicting model 204 in the information processing apparatus according to the present embodiment is described.

FIG. 2B is a flowchart showing a process of creating the optical characteristic predicting model 204 in the calculation processing unit 200.

First, a data acquiring process is performed to acquire each data recorded in the information accumulation unit 110 (step S301).

Specifically, in step S301, the measurement results of the temperature and the pressure of the projecting optical system 15 by the thermometer and the manometer mounted in the projecting optical system 15, and the target temperature and the target pressure of the projecting optical system 15 by the projecting optical system adjustment unit 20 are acquired from the information accumulation unit 110.

Further, in step S301, the measurement results of the temperature, the humidity, and the pressure in the chamber 10 by the environment meter mounted in the chamber 10 and the target temperature, the target humidity, and the target pressure in the chamber 10 by the chamber adjustment unit 30 are acquired from the information accumulation unit 110.

Furthermore, in step S301, the measurement result of the variation amount in the optical characteristic of the projecting optical system 15 by the variation measurement unit 40 is acquired from the information accumulation unit 110.

In addition, in step S301, exposure parameters such as the configuration of the illuminating optical system 12, the target illuminance of the exposure light source 11 in exposure, the transmissivity and pattern information (type) of the mask 13, and the movement speed of the substrate stage 17 are acquired from the information accumulation unit 110.

In addition, in step S301, the target position of each unit including the illuminating optical system 12, the mask stage 14, the projecting optical system 15, and the substrate stage 17 in the exposure apparatus 100 controlled by the controller 60 are acquired from the information accumulation unit 110.

Next, a data determining process is performed to classify each data acquired in step S301 into the input data and the correct answer data for creating the optical characteristic predicting model 204 (step S302).

Specifically, in step S302, the data indicating the cause of the variation in the optical characteristic of the projecting optical system 15 is classified into the input data, and the data indicating the variation in the optical characteristic of the projecting optical system 15 is classified into the correct answer data among each data acquired in step S301.

More specifically, in step S302, the measurement result of the variation amount in the optical characteristic of the projecting optical system 15 by the variation measurement unit 40 is classified into the correct answer data, and the other data is classified into the input data, among each data acquired in step S301.

Next, a model creating process of creating the optical characteristic predicting model 204 is performed by using the input data and the correct answer data acquired in step S302 (step S303).

Specifically, in step S303, the optical characteristic predicting model 204 is created by performing supervised learning with using the correct answer data acquired in step S302 as teaching data.

The creation of the optical characteristic predicting model 204 in step S303 may be performed by using data recorded in the information accumulation unit 110 during a predetermined period, or may be repeatedly performed every time new data is recorded in the information accumulation unit 110.

Next, a specific example of the information processing apparatus according to the present embodiment is described.

In the projecting optical system 15 of the exposure apparatus 100, temperatures of an optical member and an optical path space change due to thermal energy generated when exposure light passes therethrough.

Further, when the optical member is deformed or a refractive index of air in the optical path space changes by changing the temperatures of the optical member and the optical path space in the projecting optical system 15, a condensed position of the exposure light by the projecting optical system 15 changes.

Then, a line width of a pattern of a mask 13 formed on a substrate 16 is changed by changing the condensed position of the exposure light by the projecting optical system 15.

In the exposure apparatus 100, first, a substrate stage 17 is driven to align an optical sensor 18 mounted on the substrate stage 17 with a position of an imaging plane of the projecting optical system 15.

Then, a variation amount in the Z direction of the imaging plane of the projecting optical system 15 (to be referred to as a focus variation amount hereinafter) is measured from a variation in a light amount of the exposure light input to the optical sensor 18.

Specifically, the focus variation amount is measured based on an instruction of software included in the variation measurement unit 40.

Thereafter, when exposure is performed, the controller 60 controls the position in the Z direction of the substrate stage 17 and a position of a correcting mechanism of the projecting optical system 15 based on the measured focus variation amount to correct the focus variation amount.

Since such measurement of the focus variation amount needs to be performed at a timing different from that of exposure, a productivity of the exposure apparatus 100 decreases if the measurement of the focus variation amount is frequently performed.

Accordingly, in order to suppress the decrease in the productivity, the exposure apparatus 100 does not measure the focus variation amount every time the substrate 16 is exposed, but measures it when a predetermined period sufficiently longer than a processing time of the exposure has elapsed.

On the other hand, when such long measurement interval is set in the measurement of the focus variation amount, an exposure performance of the exposure apparatus 100 deteriorates when the substrate 16 is exposed in a state in which the focus variation amount due to the temperature variation of the projecting optical system 15 is not sufficiently corrected.

Accordingly, the information processing apparatus according to the present embodiment predicts the focus variation amount by creating the optical characteristic predicting model 204 such that the focus variation amount can be corrected with high accuracy when the exposure is performed on the substrate 16 even if the measurement interval of the focus variation amount is set to be sufficiently long.

Specifically, in order to predict the focus variation amount in the information processing apparatus according to the present embodiment, first, it is necessary to perform a learning phase for creating the optical characteristic predicting model 204.

Thereafter, the process proceeds to an operation phase in which the focus variation amount is predicted by using the created optical characteristic predicting model 204.

In the learning phase for creating the optical characteristic predicting model 204, first, the variation measurement unit 40 performs the measurement of the focus variation amount at a frequency of once every four hours for three months, for example, to accumulate the measurement result of the focus variation amount in the information accumulation unit 110.

Further, in parallel with the accumulation of the measurement result of the focus variation amount, the operation information and the state information of the exposure apparatus 100 are accumulated in the information accumulation unit 110 at a frequency of once a minute, for example.

Then, the optical characteristic predicting model 204 is created by performing the processes in the above-described steps S301 to S303 by using the measurement result of the focus variation amount, and the operation information and the state information of the exposure apparatus 100 accumulated in the information accumulation unit 110.

When the optical characteristic predicting model 204 is created in step S303, a known machine learning algorithm such as a neural network is used.

Next, in the operation phase in which the focus variation amount is predicted by using the created optical characteristic predicting model 204, the operation information and the state information of the exposure apparatus 100 are accumulated in the information accumulation unit 110 at a frequency of once a minute, for example, as in the learning phase.

Thereafter, the steps S201 to S203 are performed by using the operation information and state information of the exposure apparatus 100 accumulated in the information accumulation unit 110 and the optical characteristic predicting model 204 created in the learning phase. Thereby, the correction amount of each unit in the exposure apparatus 100 for correcting the focus variation amount is calculated.

When the substrate 16 is exposed, the controller 60 controls each unit in the exposure apparatus 100 based on the calculated correction amount of each unit.

Further, in the operation phase, the variation measurement unit 40 measures the focus variation amount at a frequency of once a day, for example.

Then, the measurement result of the focus variation amount and the focus variation amount predicted from the optical characteristic predicting model 204 are compared with each other to evaluate the optical characteristic predicting model 204.

As a result of the comparison, when a difference between the measurement result of the focus variation amount and the focus variation amount predicted from the optical characteristic predicting model 204 is small, specifically, smaller than a predetermined threshold value, the measurement result of the focus variation amount is accumulated in the information accumulation unit 110.

On the other hand, when the difference is large, specifically, larger than the predetermined threshold value, the measurement result of the focus variation amount is accumulated in the information accumulation unit 110, and the optical characteristic predicting model 204 is updated (recreated).

For example, when the structure in the exposure apparatus 100 is updated by replacing the illuminating optical system 12, the difference between the measurement result of the focus variation amount and the focus variation amount predicted from the optical characteristic predicting model 204 may increase.

Note that the optical characteristic predicting model 204 is updated by performing the above-described steps S301 to S303 by using the measurement result of the focus variation, and the operation information and the state information of the exposure apparatus 100 accumulated in the information accumulation unit 110 in the operation phase.

Here, when the number of measurement results of the focus variation amount accumulated in the information accumulation unit 110 in the operation phase is small, the measurement results of the focus variation amount accumulated in the information accumulation unit 110 in the learning phase may be used.

Further, the update of the optical characteristic predicting model 204 is not limited to the timing when the above-described evaluation of the optical characteristic predicting model 204 is performed, and may be performed at an arbitrary timing such as a frequency of once every six months.

As described above, the information processing apparatus according to the present embodiment creates the optical characteristic predicting model 204 by using the measurement result of the focus variation amount, and the operation information and the state information of the exposure apparatus 100.

Then, it is not necessary to stop the exposure in order to measure the focus variation amount by predicting the focus variation amount by using the created optical characteristic predicting model 204, and thus it is possible to suppress a decrease in the productivity and to maintain the exposure performance with high accuracy.

In the above description, the calculation processing unit 200 in the exposure apparatus 100 acquires each data to create the optical characteristic predicting model 204 in the learning phase, and predicts the focus variation amount by using the optical characteristic predicting model 204 in the operation phase, but the present embodiment is not limited to this.

For example, in the learning phase, the optical characteristic predicting model 204 may be created from the measurement result of the focus variation amount in an exposure apparatus A different from the exposure apparatus 100, and the operation information and the state information of the exposure apparatus 100.

Further, the optical characteristic predicting model 204 thus created may be mounted in the calculation processing unit 200 in an exposure apparatus B different from the exposure apparatus 100 and the exposure apparatus A, and the focus variation amount may be predicted by using the optical characteristic predicting model 204 in the operation phase in the exposure apparatus B.

Furthermore, it is possible to create the optical characteristic predicting model 204 by using data acquired in each of a plurality of exposure apparatuses.

In the information processing apparatus according to the present embodiment, a sensor other than the sensors shown in Table 1 can be used, and information acquired by the sensor can be used as teaching data for creating the optical characteristic predicting model 204.

Although the information processing apparatus according to the present embodiment uses a plurality of parameters of the operation information and the state information of the exposure apparatus 100 as input data, the effect of the present embodiment can be obtained by using at least the target temperature of the projecting optical system 15 by the projecting optical system adjustment unit 20 as input data.

Although the information processing apparatus according to the present embodiment predicts the focus variation amount of the projecting optical system 15, the present embodiment is not limited to this, and the information processing apparatus may predict a variation amount in an optical characteristic of another optical system such as the illuminating optical system 12.

Further, in the above description, an example is shown in which the information processing apparatus according to the present embodiment is mounted in the exposure apparatus 100, but the present embodiment is not limited to this, and the information processing apparatus can also be mounted in an exposure apparatus in another form or a pattern forming apparatus.

### Second Embodiment

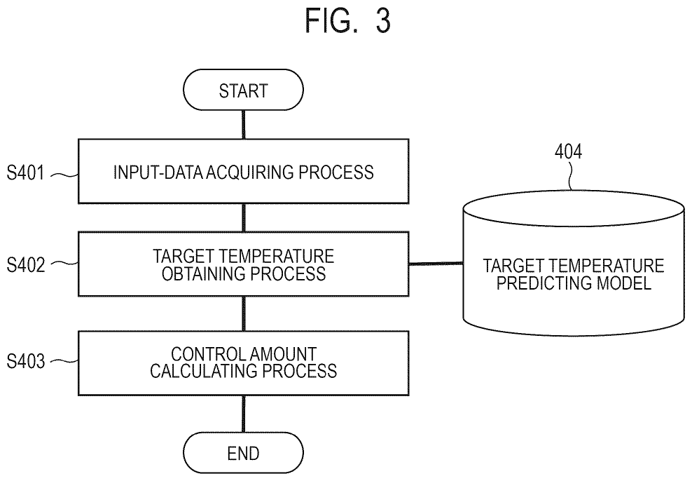

FIG. 3 is a flowchart showing a process for correcting the variation amount in the optical characteristic of the projecting optical system 15 in the calculation processing unit 200 as an information processing apparatus according to a second embodiment of the present invention.

Note that the exposure apparatus in which the information processing apparatus according to the present embodiment is mounted has the same structure as the exposure apparatus 100, so that the same members are assigned the same reference numerals, and explanations thereof are omitted.

The information processing apparatus according to the present embodiment is different from the information processing apparatus according to the first embodiment in that a target temperature predicting model 404 for predicting the target temperature of each of the projecting optical system adjustment unit 20 and the chamber adjustment unit 30 is created, and the target temperature is predicted by using the target temperature predicting model 404.

Specifically, the information processing apparatus according to the present embodiment, first, acquires each data recorded in the information accumulation unit 110 by performing step S301 in the same manner as the information processing apparatus according to the first embodiment.

Further, the target temperatures of the projecting optical system adjustment unit 20 and the chamber adjustment unit 30 are classified into the correct answer data, and the other data is classified into the input data among each data acquired in step S301 by performing step S302 in the same manner as the information processing apparatus according to the first embodiment.

Then, the target temperature predicting model 404 is created by using the input data and the correct answer data acquired in step S302 by performing step S303 in the same manner as the information processing apparatus according to the first embodiment.

Specifically, in step S303, the target temperature predicting model 404 is created by performing supervised learning in which the correct answer data acquired in step S302 is used as teaching data.

Next, the information processing apparatus according to the present embodiment performs an input-data acquiring process for converting each data recorded in the information accumulation unit 110 into input data (step S401), as shown in FIG. 3.

Specifically, in step S401, the measurement results of the temperature and the pressure of the projecting optical system 15 by the thermometer and the manometer mounted in the projecting optical system 15, and the target pressure of the projecting optical system 15 by the projecting optical system adjustment unit 20 are obtained from the information accumulation unit 110.

Further, in step S401, the measurement result of the variation amount in the optical characteristic of the projecting optical system 15 by the variation measurement unit 40 at least at a predetermined timing, for example, the latest measurement result thereof is obtained from the information accumulation unit 110.

Furthermore, in step S401, the measurement results of the temperature, the humidity, and the pressure in the chamber 10 by the environment meter mounted in the chamber 10 and the target humidity and the target pressure in the chamber 10 by the chamber adjustment unit 30 are obtained from the information accumulation unit 110.

In addition, in step S401, the target position of each unit including the illuminating optical system 12, the mask stage 14, the projecting optical system 15, and the substrate stage 17 in the exposure apparatus 100 controlled by the controller 60 is obtained from the information accumulation unit 110.

In addition, in step S401, exposure parameters such as the configuration of the illuminating optical system 12, the target illuminance of the exposure light source 11 in exposure, the transmissivity and pattern information (type) of the mask 13, and the movement speed of the substrate stage 17 in exposure are obtained from the information accumulation unit 110.

Next, a target temperature obtaining process for obtaining the target temperatures of the projecting optical system adjustment unit 20 and the chamber adjustment unit 30 for suppressing the variation in the optical characteristic of the projecting optical system 15 is performed by inputting the input data acquired in step S401 to the target temperature predicting model 404 (step S402).

The target temperature predicting model 404 used in step S402 is a mathematical model which outputs the target temperatures of the projecting optical system adjustment unit 20 and the chamber adjustment unit 30 as output data from the input data acquired in step S401.

Then, the control amounts of the projecting optical system adjustment unit 20 and the chamber adjustment unit 30 for setting the target temperatures of the projecting optical system adjustment unit 20 and the chamber adjustment unit 30 obtained in step S402 are calculated (step S403).

By setting the target temperature of each of the projecting optical system adjustment unit 20 and the chamber adjustment unit 30 in this manner, the variation amount in the optical characteristic of the projecting optical system 15 can be corrected.

As described above, the information processing apparatus according to the present embodiment creates the target temperature predicting model 404 by using the measurement result of the optical characteristic of the projecting optical system 15, and the operation information and the state information of the exposure apparatus 100.

Then, the target temperatures of the projecting optical system adjustment unit 20 and the chamber adjustment unit 30 are predicted by using the created target temperature predicting model 404, and the control amounts of the projecting optical system adjustment unit 20 and the chamber adjustment unit 30 for setting the target temperatures are calculated.

Thereby, it is not necessary to stop the exposure in order to measure the focus variation amount, and thus it is possible to suppress a decrease in the productivity and to maintain the exposure performance with high accuracy.

Note that the process of correcting the variation amount in the optical characteristic of the projecting optical system 15 in steps S401 to S403 described above may be performed every time exposure is performed on the substrate 16, or may be performed every time exposure is completed for a predetermined number of substrates 16.

Further, the process of correcting the variation amount in the optical characteristic of the projecting optical system 15 may be performed every time a parameter other than the target temperature of each of the projecting optical system adjustment unit 20 and the chamber adjustment unit 30 changes, or may be performed by predicting the parameter other than the target temperature.

Although preferred embodiments have been described above, the present invention is not limited to these embodiments, and various modifications and changes can be made within the scope of the gist of the present invention.

Further, although the information processing apparatus according to the present invention has been described above, the above-described information processing method, a program for implementing (executing) the method, and a computer-readable recording medium in which the program is recorded are also included in the scope of the present invention.

According to the present invention, an information processing apparatus capable of acquiring a variation amount in an optical characteristic of an optical system provided in an exposure apparatus in consideration of control for suppressing temperature change of the optical system, can be provided.

### [Method for Manufacturing Article]

The method for manufacturing an article according to the present invention is suitable for manufacturing an article such as a semiconductor device, a liquid crystal displaying element, a flat panel display, or a microelectromechanical system (MEMS).

Specifically, the method of manufacturing an article according to the present invention includes a step of exposing a photosensitive agent applied on a substrate by using the exposure apparatus 100 including the above-described information processing apparatus according to the present invention, and a step of developing the photosensitive agent exposed in the exposing step.

Next, a circuit pattern is formed on the substrate by performing an etching process, an ion implantation process or the like on the substrate by using the developed pattern of the photosensitive agent as a mask.

Then, the circuit pattern including a plurality of layers is formed on the substrate by repeatedly performing these processes such as the exposure, the development, and the etching.

Next, as a post-process, dicing (processing) is performed on the substrate on which the circuit pattern is formed, and mounting, bonding, and an inspection process of the formed chip are performed.

Further, the method for manufacturing an article according to the present invention can include other well-known processing steps such as oxidation, film formation, vapor deposition, doping, planarization, and removal of the photosensitive agent.

The method for manufacturing an article according to the present invention is advantageous in at least one of performance, quality, productivity, and production cost of the article as compared to conventional methods.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

What is claimed is:

1. An information processing apparatus configured to predict a variation amount in an optical characteristic of an optical system provided in an exposure apparatus by inputting a target temperature of the optical system to a learning model,
wherein the learning model is a learning model obtained by machine learning.

2. The information processing apparatus according to claim 1, wherein the information processing apparatus is configured to predict the variation amount in the optical characteristic of the optical system by further inputting at least one of a measurement result of a temperature of the optical system, a measurement result of a pressure of the optical system, a target pressure of the optical system, a measurement result of a temperature in a chamber in which an exposure light source, an original stage, the optical system and a substrate stage in the exposure apparatus are accommodated, a measurement result of a humidity in the chamber, a measurement result of a pressure in the chamber, a target temperature in the chamber, a target humidity in the chamber, a target pressure in the chamber, a target position of the original stage, a target position of the optical system, a target position of the substrate stage, a configuration of the optical system, a target illuminance of the exposure light source when an exposure is performed, a type of an original used when the exposure is performed, and a movement speed of the substrate stage when the exposure is performed, to the learning model.

3. The information processing apparatus according to claim 1, wherein input data of the learning model is created from at least one of the target temperature of the optical system, a measurement result of a temperature of the optical system, a measurement result of a pressure of the optical system, a target pressure of the optical system, a measurement result of a temperature in a chamber in which an exposure light source, an original stage, the optical system and a substrate stage in the exposure apparatus are accommodated, a measurement result of a humidity in the chamber, a measurement result of a pressure in the chamber, a target temperature in the chamber, a target humidity in the chamber, a target pressure in the chamber, a target position of the original stage, a target position of the optical system, a target position of the substrate stage, a configuration of the optical system, a target illuminance of the exposure light source when an exposure is performed, a type of an original used when the exposure is performed, and a movement speed of the substrate stage when the exposure is performed.

4. The information processing apparatus according to claim 1, wherein correct answer data of the learning model is created from a measurement result of the variation amount in the optical characteristic of the optical system.

5. The information processing apparatus according to claim 1, wherein the information processing apparatus is configured to:
create input data from at least one of the target temperature of the optical system, a measurement result of a temperature of the optical system, a measurement result of a pressure of the optical system, a target pressure of the optical system, a measurement result of a temperature in a chamber in which an exposure light source, an original stage, the optical system and a substrate stage in the exposure apparatus are accommodated, a measurement result of a humidity in the chamber, a measurement result of a pressure in the chamber, a target temperature in the chamber, a target humidity in the chamber, a target pressure in the chamber, a target position of the original stage, a target position of the optical system, a target position of the substrate stage, a configuration of the optical system, a target illuminance of the exposure light source when an exposure is performed, a type of an original used when the exposure is performed, and a movement speed of the substrate stage when the exposure is performed;
create correct answer data from a measurement result of the variation amount in the optical characteristic of the optical system; and
create the learning model by performing machine learning based on the created input data and the created correct answer data.

6. The information processing apparatus according to claim 5, wherein the information processing apparatus is configured to update the learning model when a difference between the variation amount in the optical characteristic of the optical system predicted from the learning model and a measurement result of the variation amount in the optical characteristic of the optical system is larger than a predetermined threshold.

7. The information processing apparatus according to claim 5, wherein the information processing apparatus is configured to:
create the input data and the correct answer data in a plurality of exposure apparatuses; and
create the learning model by performing machine learning based on the created input data and the created correct answer data.

8. The information processing apparatus according to claim 1, wherein the optical characteristic of the optical system includes at least one of a focus and a distortion of the optical system.

9. An exposure apparatus configured to expose a substrate so as to transfer a pattern formed on an original onto the substrate, comprising:
a projecting optical system configured to guide exposure light passing through the original to the substrate;
a projecting optical system adjustment unit configured to control a temperature of the projecting optical system;
the information processing apparatus according to claim 1 configured to predict a variation amount in an optical characteristic of the projecting optical system; and
a controller configured to control a position of the projecting optical system based on the variation amount in the optical characteristic of the projecting optical system predicted by the information processing apparatus.

10. The exposure apparatus according to claim 9, further comprising:
an exposure light source configured to emit the exposure light;
an illuminating optical system configured to guide the exposure light from the exposure light source to the original;
an original stage on which the original is placed;
a substrate stage on which the substrate is placed;
a chamber in which the exposure light source, the illuminating optical system, the original stage, the projecting optical system, and the substrate stage are accommodated;
the projecting optical system adjustment unit configured to control a pressure of the projecting optical system;
a chamber adjustment unit configured to control a temperature, a humidity, and a pressure in the chamber;
the controller configured to control a position of the illuminating optical system, a position of the original stage, a position of the substrate stage, and an illuminance of the exposure light source; and
a measurement unit configured to measure the variation amount in the optical characteristic of the projecting optical system.

11. The exposure apparatus according to claim 10, further comprising a storing unit configured to record at least one of a target temperature of the projecting optical system, a measurement result of a temperature of the projecting optical system, a measurement result of a pressure of the projecting optical system, a target pressure of the projecting optical system, a measurement result of a temperature in the chamber, a measurement result of a humidity in the chamber, a measurement result of a pressure in the chamber, a target temperature in the chamber, a target humidity in the chamber, a target pressure in the chamber, a target position of the illuminating optical system, a target position of the original stage, a target position of the projecting optical system, a target position of the substrate stage, a configuration of the illuminating optical system, a target illuminance of the exposure light source when the exposure is performed, a type of the original, and a movement speed of the substrate stage when the exposure is performed.

12. A method for manufacturing an article, comprising:
exposing the substrate by using the exposure apparatus according to claim 9;
developing the exposed substrate; and
manufacturing an article from the developed substrate.

13. An information processing method comprising predicting a variation amount in an optical characteristic of an optical system by inputting a target temperature of the optical system provided in an exposure apparatus to a learning model,
wherein the learning model is a learning model obtained by machine learning.

14. A computer-readable recording medium recording a program for causing a computer to perform an information process, the program causing the computer to execute the information processing method according to claim 13.

15. An information processing apparatus configured to predict a target temperature of an optical system provided in an exposure apparatus by inputting a variation amount in an optical characteristic of the optical system to a learning model,
wherein the learning model is a learning model obtained by machine learning.
